(19) United States
(12) Patent Application Publication
(10) Pub. No.: US 2022/0385039 A1
(43) Pub. Date: Dec. 1, 2022

(54) SUBSTRATE DESIGNS FOR TIME-OF-FLIGHT CAMERA PROJECTORS WITH LOW THERMAL RESISTANCE AND LOW PARASITIC INDUCTANCE

(71) Applicant: Lumentum Operations LLC, San Jose, CA (US)

(72) Inventors: Wei SHI, San Jose, CA (US); Hao HUANG, San Jose, CA (US); Siu Kwan CHEUNG, San Jose, CA (US); Huanlin ZHU, San Jose, CA (US); Lijun ZHU, Dublin, CA (US)

(21) Appl. No.: 17/445,787

(22) Filed: Aug. 24, 2021

Related U.S. Application Data
(60) Provisional application No. 63/202,620, filed on Jun. 17, 2021.
(60) Provisional application No. 63/202,153, filed on May 28, 2021.

(51) Int. Cl. H01S 5/183; G01S 7/4865; G01S 17/894; H01S 5/028

(52) U.S. Cl. CPC H01S 5/18302; G01S 7/4865; G01S 17/894; H01S 5/18369; H01S 5/0281

(57) ABSTRACT

A circuit (e.g., for use in a time-of-flight camera projector module) may include a top metal layer having an anode and a cathode, one or more capacitors connected to the anode, a vertical-cavity surface-emitting laser connected to the anode and the cathode, and a driver connected to the cathode. The circuit may further include a bottom metal layer connected to ground and arranged below the top metal layer, and a dielectric layer separating the top metal layer and the bottom metal layer. In some implementations, the dielectric layer has a thickness under sixty micrometers and a thermal resistance under fifteen degrees Celsius per watt. Accordingly, a current loop flowing vertically across the dielectric layer has a low self-inductance based on the thickness of the dielectric layer and the bottom metal layer is arranged to dissipate heat generated by the current loop flowing vertically across the dielectric layer.

### CROSS-REFERENCE TO RELATED APPLICATIONS

This patent application claims priority to U.S. Provisional Patent Application No. 63/202,153, filed on May 28, 2021, and entitled “PACKAGING SUBSTRATE WITH LOW THERMAL RESISTANCE AND LOW PARASITIC INDUCTANCE,” and to U.S. Provisional Patent Application No. 63/202,620, filed on Jun. 17, 2021, and entitled “HYBRID SUBSTRATE DESIGN FOR TIME-OF-FLIGHT CAMERA PROJECTORS WITH LOW THERMAL RESISTANCE AND LOW PARASITIC INDUCTANCE.” The disclosures of the prior applications are considered part of and incorporated by reference into this patent application.

### TECHNICAL FIELD

The present disclosure relates generally to substrate designs for forming a current loop across two metal layers and to time-of-flight (ToF) projector modules in which a current loop is formed in two metal layers that are separated by a thin dielectric coating or a thin dielectric layer that has a low thermal resistance and a low parasitic inductance.

### BACKGROUND

In electromagnetism, a dielectric or dielectric material is an electrical insulator or a very poor conductor of electric current that can be polarized by an applied electric field. When a dielectric material is placed in an electric field, electric charges do not flow through the dielectric material in the same way that electric charges flow through an electrical conductor (e.g., metal) because dielectric materials have no loosely bound or free electrons that may drift through the dielectric material. Instead, in a dielectric material, electric charges only slightly shift from average equilibrium positions, causing dielectric polarization. For example, positive charges within the dielectric material are displaced minutely in a direction of the electric field, and negative charges are displaced minutely in a direction opposite to the electric field. The slight separation of charge (or polarization) reduces the electric field within the dielectric material such that practically no electric current flows in the dielectric material.

### SUMMARY

In some implementations, a circuit includes a top metal layer that includes an anode and a cathode; one or more capacitors connected to the anode; a vertical-cavity surface-emitting laser (VCSEL) connected to the anode and the cathode; a driver connected to the cathode; a bottom metal layer arranged below the top metal layer, wherein the bottom metal layer is connected to ground; and a dielectric layer separating the top metal layer and the bottom metal layer, wherein the dielectric layer has a thickness under sixty (60) micrometers (μm) and a thermal resistance under fifteen (15) degrees Celsius per watt (C/W), wherein a current loop flowing vertically across the dielectric layer has a low self-inductance based on the thickness of the dielectric layer, and wherein the bottom metal layer is arranged to dissipate heat generated by the current loop flowing vertically across the dielectric layer.

In some implementations, a projector module includes a housing; a substrate attached to the housing, wherein the substrate includes: a metal core having a top side and a bottom side; a first metal circuit layer formed above the top side of the metal core; a second metal circuit layer formed below the bottom side of the metal core; a first dielectric coating separating the metal core from the first metal circuit layer; and a second dielectric coating separating the metal core from the second metal circuit layer, wherein the first dielectric coating and the second dielectric coating have respective thicknesses that are each less than sixty (60) μm and respective thermal resistances that are each less than fifteen (15) C/W; one or more circuit components on the first metal circuit layer, wherein the one or more circuit components include: one or more capacitors; a driver; and a VCSEL connected to the one or more capacitors and the driver, wherein a current loop flowing horizontally through the one or more circuit components and vertically across at least the first dielectric coating causes the VCSEL to emit a laser beam in a vertical direction, and wherein the current loop has a low self-inductance based on the thickness of at least the first dielectric coating.

In some implementations, a projector module includes a substrate that includes a cavity; a submount, bonded to the cavity in the substrate, wherein the submount includes: a metal base block; a dielectric coating on a top side of the metal base block, wherein the dielectric coating has a thickness that is twenty (20) μm or less; and a metal circuit layer formed above the dielectric coating; and one or more circuit components on the metal circuit layer, wherein the one or more circuit components include: one or more capacitors; a driver; and a VCSEL connected to the one or more capacitors and the driver, wherein a current loop flowing horizontally through the one or more circuit components and vertically across at least the dielectric coating causes the VCSEL to emit a laser beam in a vertical direction, and wherein the current loop has a low self-inductance and a low thermal resistance based on the thickness of the dielectric coating.

### BRIEF DESCRIPTION OF THE DRAWINGS

FIG. 1 is a diagram illustrating an example of a complementary metal-oxide-semiconductor (CMOS) chip.

FIG. 2 is a diagram illustrating examples of top-emitting vertical-cavity surface-emitting laser (VCSEL) chips.

FIGS. 3A-3B are diagrams illustrating example implementations of substrates with a low thermal resistance and a low parasitic inductance.

FIGS. 4A-4B are diagrams illustrating example implementations of a package or hybrid substrate that includes a submount with a low thermal resistance and a low parasitic inductance.

FIG. 5A is a diagram illustrating an example of a time-of-flight (ToF) projector module.

FIGS. 5B-5D are diagrams illustrating examples of current loops that may be used to drive an optical load in a ToF projector module.

FIG. 6 is a diagram illustrating an example implementation of a ToF projector module in which a current loop used to drive an optical load is formed vertically across two metal layers in a substrate with a low thermal resistance and a low parasitic inductance.

FIGS. 7A-7C are diagrams illustrating example implementations of a ToF projector module in which a current loop used to drive an optical load is formed vertically across two metal layers in a submount with a low thermal resistance and a low parasitic inductance.

### DETAILED DESCRIPTION

The following detailed description of example implementations refers to the accompanying drawings. The same reference numbers in different drawings may identify the same or similar elements.

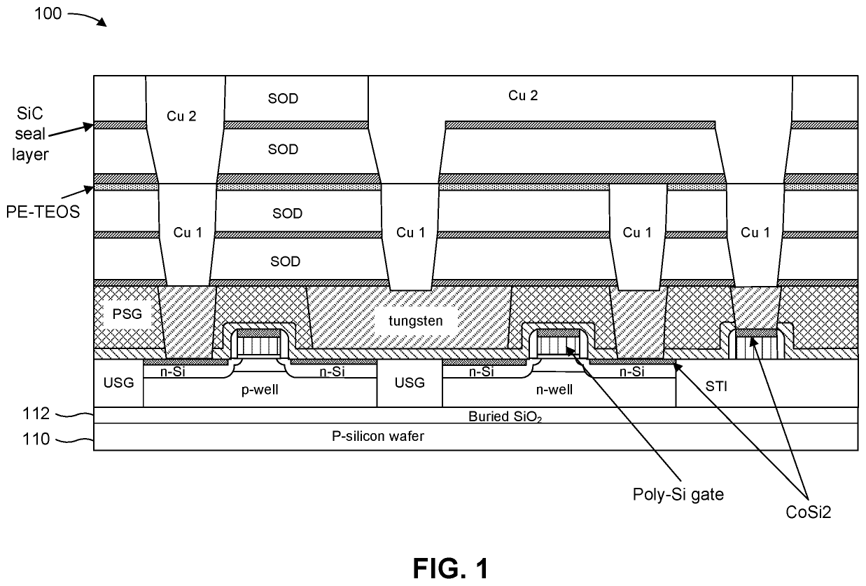

In a conventional integrated circuit (IC) chip, a top side is typically designed for electrical connection to one or more electrodes and/or a ball grid array (BGA) by wire bond, solder balls, and/or other suitable elements, and a bottom side is electrically isolated such that a substrate under a silicon chip area can be designed purely for heat dissipation. For example, FIG. 1 illustrates an example 100 of a complementary metal-oxide-semiconductor (CMOS) chip in which electrical current does not flow down to a silicon wafer 110 because a buried silicon dioxide (SiO₂) layer 112 electrically isolates the silicon wafer 110. Accordingly, the bottom side of the IC chip is electrically insulated in conventional IC chip designs, and electric current flows out one surface (e.g., the top surface) rather than vertically through the IC chip.

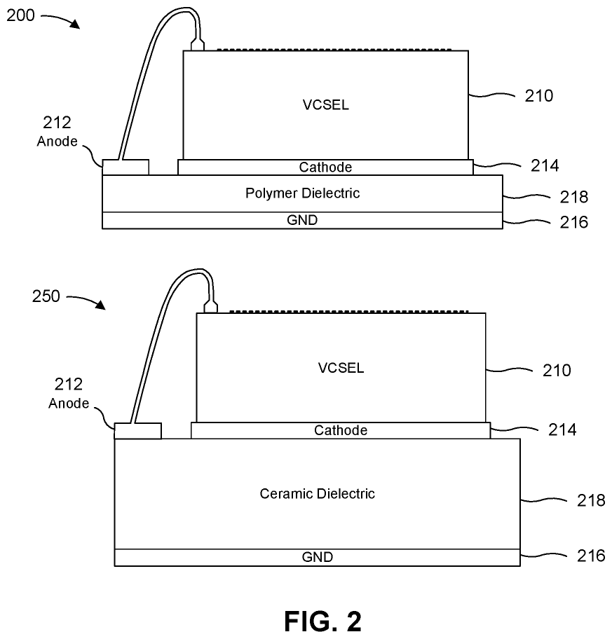

In contrast, a vertical-cavity surface-emitting laser (VCSEL) chip is generally designed to emit a laser beam in a direction perpendicular to a substrate surface (e.g., vertically from a surface of a semiconductor wafer), which differs from conventional IC chip designs in that electrical current and heat both flow from a top surface of the VCSEL chip to the bottom surface and then to a die pad or cathode layer. For example, FIG. 2 is a diagram illustrating examples 200, 250 of top-emitting VCSEL chips. As shown in FIG. 2, and by examples 200, 250, a top-emitting VCSEL chip generally includes a VCSEL 210 that emits a laser beam in a vertical direction, an anode 212, a cathode 214, a ground layer 216, and a dielectric layer 218 that separates the anode 212 and the cathode 214 from the ground layer 216. For example, as shown in FIG. 2, electric current flows from the anode 212 to the top surface of the VCSEL 210, vertically through the VCSEL 210 to the cathode 214, and then horizontally through the cathode 214 to a neighboring controller, an IC driver, and/or another suitable component (not shown). Accordingly, because both heat and electrical current flow vertically through the VCSEL 210 from the anode 212 to the cathode 214, the underlying substrate needs to have at least two metal layers.

For example, in the underlying substrate design, the cathode 214 is needed to enable electric current to flow through the VCSEL 210 to the neighboring controller, IC driver, and/or other suitable component(s), and the ground layer 216 is needed under the cathode 214 to support high-speed signals. Accordingly, the dielectric layer 218 is needed to electrically insulate the electric current that flows horizontally through the cathode 214 and to separate the cathode 214 from a heat dissipation pad on the substrate bottom (e.g., because the heat dissipation pad is typically electrically grounded and cannot be connected to the cathode 214 directly). However, the dielectric layer 218 that is needed between the cathode 214 and the ground layer 216 poses various design challenges. In particular, because both heat and electric current flow vertically through the VCSEL 210, the dielectric layer 218 needs to provide electrical insulation for the electric current, and the dielectric layer 218 further needs to have a low thermal resistance such that a heat dissipation pad (not shown) under the ground layer 216 can dissipate and/or spread the heat that flows vertically through the VCSEL 210.

For example, in FIG. 2, example 200 depicts a VCSEL chip in which the dielectric layer 218 is made from a polymer dielectric material, such as flame retardant 4 (FR4 or FR-4), which is a flame resistant or self-extinguishing composite material made from woven fiberglass cloth with an epoxy resin binder. In such cases, when the dielectric layer 218 is made from a polymer dielectric such as FR4, the dielectric layer 218 has a very low thermal conductivity (e.g., approximately 0.3 to approximately 0.7 watts per meter-kelvin (W/mK)). As a result, even if advanced substrate technology were to be used to form the dielectric layer 218 with a minimum thickness for the chosen polymer dielectric material (e.g., 25 micrometers (μm) for FR4) to optimize electrical performance (e.g., by minimizing parasitic inductance across the dielectric layer 218, between the cathode 214 and the ground layer 216), the low thermal conductivity of the polymer dielectric material results in a high thermal resistance (e.g., 46.61 degrees Celsius per watt (C/W) for FR4). In other words, the very high thermal resistance of polymer dielectric materials blocks the dissipation and/or spreading of heat that flows vertically through the VCSEL 210, which in turn downgrades optical output power from the VCSEL 210.

Alternatively, example 250 in FIG. 2 depicts a VCSEL chip in which the dielectric layer 218 is made from a ceramic material (e.g., aluminum nitride (AlN) or aluminum oxide (Al₂O₃)). In such cases, the thermal conductivity of the ceramic dielectric material may be somewhat higher than the thermal conductivity of a polymer dielectric material (e.g., 130 W/mK for AlN or 15 W/mK for Al₂O₃ at a typical VCSEL operating temperature). However, in such cases, the dielectric layer 218 may have a large thickness (e.g., a minimum thickness of 100 μm for MN, or a minimum thickness of 70 μm for Al₂O₃) due to substrate manufacturing constraints. Accordingly, thermal resistance is not significantly reduced due to the very large thickness of the dielectric layer 218, which also increases parasitic inductance to a higher level that has an impact on high-speed signal quality (e.g., by degrading high-speed modulation performance). In other words, although ceramic dielectric materials such as AlN and Al₂O₃ generally have better thermal conductivity (lower thermal resistance) than polymer dielectric materials such as FR4, the large thickness of the dielectric layer 218 in example 250 results in suboptimal thermal performance (e.g., insufficient heat spreading and dissipation) and suboptimal electrical performance (e.g., a very high parasitic inductance).

Accordingly, existing substrates that are typically used in the IC packaging industry suffer from drawbacks less than ideal for use with a VCSEL chip where heat and electrical current flow vertically through the VCSEL chip, because the dielectric layer 218 used in the VCSEL chip are typically made from dielectric materials that have a high thermal resistance and/or dielectric materials that have a large minimum thickness that leads to a higher parasitic inductance. Furthermore, the drawbacks associated with existing dielectric materials are worse for VCSEL chips that are operated using high-speed signals, which generally requires more power, thereby resulting in more heat to be dissipated and/or spread and/or greater sensitivity to parasitic inductance. Furthermore, although some thin dielectric coating systems allow inorganic materials (e.g., aluminum oxynitride (AlON), AlN, aluminum phosphate (AlPO₄), and/or Al₂O₃) to be used as a coating material, these materials are usually incompatible with lamination processes used in the polymer dielectric (e.g., FR4) substrate industry and with co-firing processes used in the high temperature co-fired ceramic (HTCC) substrate industry.

Some implementations described herein relate to one or more substrate designs in which a metal core is separated from one or more metal circuit layers by one or more thin dielectric layers (or dielectric coatings) that may have a thickness between approximately 0.2 μm and approximately 60 μm. For example, in some implementations, a substrate may include a conductive core, which may be made from a metal that has a high thermal conductivity (e.g., copper, copper-tungsten, or aluminum) to enable heat dissipation or spreading, one or more metal circuit layers above the core and one or more metal circuit layers below the metal core, and a thin dielectric layer that separates each metal circuit layer from the metal core and/or an adjacent metal circuit layer. The dielectric coating layers may generally have a thickness less than approximately 60 μm and may have a thickness that is less than 25 μm in the case of AlON, AlN, or AlPO₄ (e.g., going as low as 0.2 to 5 μm for AlPO₄), which may result in a low parasitic inductance. Furthermore, the dielectric coating layers may be made from a dielectric material (e.g., AlON, AlN, AlPO₄, and/or Al₂O₃) that has a low thermal resistance (e.g., when the dielectric coating layers have a thickness of approximately 60 μm or less). In some implementations, one or more vias may be formed in the substrate by laser drilling, dielectric-epoxy filling, and copper (Cu) filling, which may be followed by Cu plating and patterning on the top and bottom surfaces. In some implementations, the one or more vias may provide an interconnect from a metal circuit layer to the metal core, may provide an interconnect that is isolated from the metal core by additional dielectric materials in the via(s) to connect metal circuit layers above and below the metal core, and/or may provide an interconnect between two metal circuit layers on the same side of the metal core (e.g., a first and second metal circuit layer above the metal core and/or a first and second metal circuit layer above the metal core) in cases where there are multiple metal circuit layers above or below the metal core.

Additionally, or alternatively, some implementations described herein relate to an integrated circuit package structure (e.g., a multi-layer hybrid substrate) including a submount that can be used as a grounding layer and a heat dissipation layer. For example, in some implementations, the submount may be packaged into or otherwise bonded to an organic substrate (e.g., an FR4 substrate) and/or an inorganic substrate (e.g., an HTCC substrate) that includes a cavity to receive the submount and an open window to emit a laser beam in a vertical direction. In some implementations, the submount may include a metal base block, a single metal circuit layer above the metal base block, and a thin dielectric layer or dielectric coating on a top surface of the metal base block to provide electrical isolation between the metal base block and the metal circuit layer. In some implementations, a single metal layer (1ML) may be separated from the bottom base block by a dielectric coating layer having a thickness between approximately 0.2 μm and approximately 60 μm, which may result in a low parasitic inductance, and the dielectric coating layer may be made from a dielectric material that has a low thermal resistance.

In this way, some implementations described herein relate to one or more substrate designs and one or more package (e.g., hybrid substrate) designs that may satisfy thermal and electrical performance requirements in circuits where heat and electrical current flows vertically across different metal layers. For example, as described herein, a dielectric layer used to electrically isolate a metal circuit layer (e.g., a cathode) that receives an electrical signal from a grounded heat dissipation pad used to spread and/or dissipate heat may be designed to have a low parasitic inductance and a low thermal resistance. For example, because the dielectric layer is ultra-thin (e.g., generally less than 60 μm, and potentially as thin as 0.2 μm), the dielectric layer is associated with a low parasitic inductance (e.g., because the parasitic inductance is proportional to a size of a current loop formed across the dielectric layer and vertically between two metal layers, whereby a thinner dielectric layer reduces parasitic inductance by reducing the size of the current loop). Furthermore, because the dielectric layer is thin and made from a dielectric material with a low thermal resistance, the dielectric layer does not interfere with the heat spreading and/or heat dissipation properties of the metal core in the substrate design(s) described herein or the metal base block in the package design(s) described herein. For example, the following table indicates thermal resistance and parasitic inductance properties for various dielectric materials, including FR4 and AlN layers with a minimum thickness of 100 μm which suffer from degraded optical output power due to high thermal resistance, poor high-speed signal quality due to a large thickness increasing electrical capacitance, and/or incompatibility with lamination, co-firing, and/or other manufacturing processes used in the substrate industry. In addition, the following table indicates thermal resistance and parasitic inductance properties for AlON that may be grown to a 20 μm thickness on a top surface and a bottom surface of a metal core, where AlON grown on copper (Cu) or copper-tungsten (CuW) exhibits comparable thermal resistance as AlN but a much lower parasitic inductance due to the very small thickness.

TABLE 1
Thermal resistance and parasitic inductance
for different dielectric materials

| Dielectric material; Thickness | Thermal resistance | Parasitic inductance |
|---|---|---|
| FR4; 25 μm | 46.61 C/W | Medium |
| AlN; 100 μm | 12.92 C/W | High |
| AlPO₄: 2 × 0.5 μm | 12.33 C/W | Low |
| (on 100 μm Cu) | | |
| AlON; 2 × 20 μm | 12.58 C/W | Low |
| (on 100 μm Cu) | | |
| AlON; 2 × 20 μm | 12.78 C/W | Low |
| (on 100 μm CuW) | | |

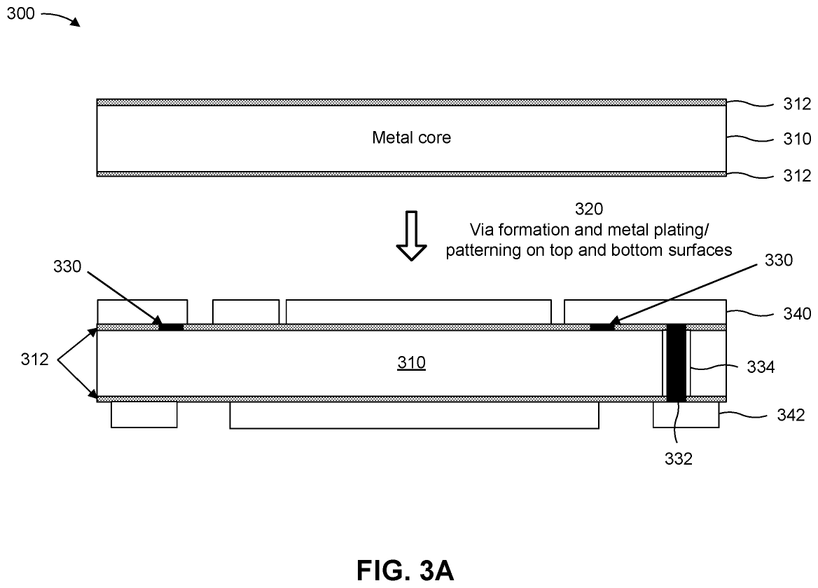

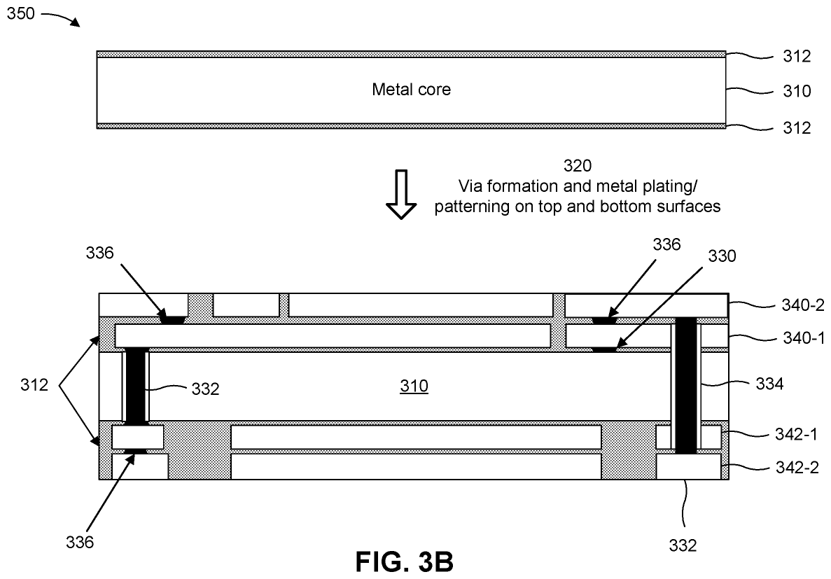

FIGS. 3A-3B are diagrams illustrating example implementations 300, 350 of substrates with a low thermal resistance and a low parasitic inductance.

For example, in FIG. 3A, implementation 300 is an example of a two-metal-layer (2ML) metal-core substrate in which a starting structure includes a thermally conductive metal core 310 that has a top side with a first dielectric coating 312 and a bottom side with a second dielectric coating 312 (e.g., 2× dielectric coating 312 on metal core 310, as in the first column of Table 1). In some implementations, as described herein, the first dielectric coating 312 and the second dielectric coating 312 may include a dielectric material that can be grown on the metal core 310 to a thickness in a range between approximately 0.2 μm and approximately 60 μm. For example, in some implementations, the dielectric material may include AlPO₄, in which case the dielectric coatings 312 have respective thicknesses between approximately 0.2-5 μm, AlON or AlN, in which case the dielectric coatings 312 have respective thicknesses between approximately 10-20 μm, or Al₂O₃, in which case the dielectric coatings 312 have respective thicknesses less than approximately 60 μm, although other dielectric materials and corresponding thicknesses may be used. Accordingly, because the dielectric coatings 312 are very thin (e.g., less than approximately 60 μm, and potentially as low as 0.2 μm in the case of AlPO₄), the dielectric coatings 312 may be associated with a very low parasitic inductance, which is mainly impacted by the thickness of the dielectric coatings 312. For example, due to the dielectric coatings 312 having a thickness of less than approximately 60 μm, a first current loop between the metal core 310 and a metal layer 340 formed above the metal core 310 (across the top dielectric coating 312) and a second current loop between the metal core 310 and a metal layer 342 formed below the metal core 310 (across the bottom dielectric coating 312) may have a shorter length, which reduces parasitic inductance. Furthermore, in some implementations, the dielectric materials that are used for the dielectric coatings 312 may have a low thermal resistance to enable heat dissipation and/or spreading in the metal core 310, which may be made from a metal that has a high thermal conductivity (e.g., Cu, CuW, or aluminum (Al)). In general, the thermal resistance of the dielectric coatings 312 may be impacted by the thickness of the dielectric coatings 312 and/or the thermal conductivity of the dielectric material used for the dielectric coatings 312. For example, a dielectric coating 312 that includes AlON at a thickness of approximately 20 μm has a high thermal conductivity that exceeds 300 W/mK and a low thermal resistance of approximately 0.06 C/W. In another example, although a dielectric coating 312 that includes AlPO₄ has a relatively lower thermal conductivity of approximately 1-1.5 W/mK, the dielectric material AlPO₄ offers acceptable thermal resistance values (e.g., minimal thermal insulation) due to having a very small thickness of approximately 0.2-5 μm.

In some implementations, as shown in FIG. 3A, and by reference number 320, the starting structure that includes the metal core 310 with the first dielectric coating 312 on the top side and the second dielectric coating 312 on the bottom side may be processed to form one or more vias and to perform metal plating and patterning on the top and bottom surfaces of the starting structure (e.g., to provide electrical connections between different layers). For example, to form a via 330 that provides an electrical connection to the metal core 310, an opening may be formed in a dielectric coating 312 (e.g., via laser drilling, etching, and/or other suitable techniques) and the opening may then be filled with a metal (e.g., Cu) to form the via 330 that provides an electrical connection to the metal core 310. In some implementations, formation of the via 330 may then be followed by metal plating and patterning on the top and bottom surfaces to form a first metal circuit layer 340 above the metal core 310 and a second metal circuit layer 342 below the metal core, where one or more of the metal circuit layers 340, 342 may be connected to the metal core 310 by a via 330. Additionally, or alternatively, to form a via 332 that provides an electrical connection that is isolated from the metal core 310, an opening may be formed through the metal core 310 and the dielectric coatings 312 on the top and bottom sides of the metal core, and the opening may then be filled with a dielectric epoxy 334 and a metal (e.g., Cu) to form the via 332 through the metal core. In this way, when formation of the via 332 is followed by metal plating and patterning on the top and bottom surfaces to form the first metal circuit layer 340 above the metal core 310 and the second metal circuit layer 342 below the metal core, the via 332 through the metal core 310 and the dielectric coatings 312 may provide an electrical interconnect between the metal circuit layer 340 above the metal core 310 and the metal circuit layer 342 below the metal core 310.

As shown in FIG. 3B, and by example implementation 350, the substrate is generally not restricted to having one metal circuit layer 340 above the metal core 310 and one metal circuit layer 342 below the metal core 310. For example, in some implementations, the starting structure that includes the metal core 310 with the dielectric coatings 312 on the top and bottom sides of the metal core 310 may be processed (e.g., in a similar manner as described above in connection with FIG. 3A) to form one or more vias 330 through a dielectric coating 312 to provide an electrical connection to the metal core 310 and/or one or more one or more vias 332 through the metal core 310 and the dielectric coatings 312 to provide an electrical connection between a metal circuit layer 340 above the metal core 310 and a metal circuit layer 342 below the metal core 310. In some implementations, as described above, the formation of the vias 330, 332 may be followed by metal plating and/or patterning to form a first metal circuit layer 340-1 above the metal core 310 and a first metal circuit layer 342-1 below the metal core 310. In some implementations, additional dielectric coating 312 may then be grown on the first metal circuit layer 340-1 above the metal core 310 and the first metal circuit layer 342-1 below the metal core 310 (e.g., to a thickness below approximately 60 μm, such as 0.2-5 μm for AlPO₄ or 10-20 μm for AlON or AlN). In some implementations, one or more additional vias 336 may then be formed in a similar manner (e.g., laser drilling followed by metal filling) to form electrical connections between adjacent metal circuit layers 340/342 (e.g., between the first metal circuit layer 340-1 and a second metal circuit layer 340-2 above the metal core 310 and/or between the first metal circuit layer 342-1 and a second metal circuit layer 342-2 below the metal core 310). Additionally, or alternatively, the vias 332 through the metal core 310 may be subject to further processing (e.g., laser drilling and metal filling) to provide electrical connections between the second metal circuit layers 340-2, 342-2 (and/or metal circuit layers 340-N, 342-N to be formed at higher or lower levels in the stack). In some implementations, additional metal plating and/or patterning may then be performed to form the second metal circuit layers 340-2, 342-2, resulting in the four-metal-layer (4ML) metal-core substrate shown in FIG. 3B.

Accordingly, as described herein, the substrate that is formed from the starting structure that includes the metal core 310 and the thin dielectric coatings 312 may generally include one or more metal circuit layers 340 above the metal core 310 and one or more metal circuit layers 342 below the metal core 310, where each metal circuit layer 340, 342 is separated from the metal core 310 and/or an adjacent metal circuit layer 340/342 by a thin dielectric coating 312 that has a low parasitic inductance to improve electrical performance and a low thermal resistance to improve heat dissipation and heat spreading properties. For example, as described herein, the dielectric coatings 312 are grown on the metal core 310 and/or a metal circuit layer 340/342 to a thickness that is generally less than approximately 60 μm and may be made from materials that have a low thermal resistance based on the thicknesses of the dielectric coatings 312. In this way, the 2ML metal-core substrate shown in FIG. 3A, the 4ML metal-core substrate shown in FIG. 3B, and/or a metal-core substrate with a similar design but a different number of metal circuit layers 340, 342 may receive a chip that requires high speed, a chip that requires a high thermal conductivity, and/or a chip that has an ungrounded bottom (e.g., a chip with minimum of two metal layers and a ground layer, which may be used in a device such as a time-of-flight (ToF) camera). Any such chips may be optical chips, or more specifically VCSEL chips. For example, the substrate designs shown in FIGS. 3A-3B include an ungrounded region that may receive a chip, a grounded region that has a low parasitic inductance, and a low thermal resistance through the region receiving the chip.

For example, in some implementations, the substrate designs shown in FIGS. 3A-3B may be used to receive a VCSEL chip that requires a bottom metal contact (e.g., a cathode layer or die pad) to be disconnected from a ground layer, a higher heat dissipation out of the bottom of the VCSEL chip, and/or high-speed signals. For example, the substrate designs shown in FIGS. 3A-3B may provide electrical isolation from a top metal circuit layer 340 to a ground layer, minimal thermal insulation for heat dissipation through the substrate based on the thickness and thermal conductivity of the dielectric coatings 312, and lower parasitic inductance between the top of the substrate and the ground layer by using thin the dielectric coatings 312 as insulating layers. In general, from top to bottom, the metal layers in the substrate designs shown in FIGS. 3A-3B may alternate between being configured as signal layers and ground layers. For example, in FIG. 3B, the metal circuit layer 340-2 may be a signal layer, the metal circuit layer 340-1 may be a ground layer, metal circuit layers 342-1 and 342-2 may be used for routing, and the metal core 310 may be used for heat dissipation. For example, the substrate designs shown in FIGS. 3A-3B generally include a metal core 310 made from a metal (e.g., Cu, CuW, Al, or the like) having a high thermal conductivity for heat dissipation and/or spreading, vias 330 to the metal core 310, vias 332 across the metal core 310, and/or vias 336 between adjacent metal circuit layers 340/342, and thin dielectric coatings 312 that may be less than 25 μm (e.g., 0.2-5 μm for AlPO₄ or 10-20 μm for AlON or AlN) and associated with thermal resistance values and capacitance or parasitic inductance values that satisfy one or more performance thresholds (e.g., depending on one or more factors, such as chip power, operating conditions, application conditions, and/or environmental conditions). For example, the thermal resistance value may satisfy a first threshold and the capacitance or parasitic inductance value may satisfy a second threshold, where the first threshold may be defined to provide thermal properties that ensure sufficient heat dissipation and/or spreading, and the second threshold may be defined to provide electrical properties that ensure sufficient high-speed signal quality.

For example, as described herein, each dielectric coating 312 may separate a metal circuit layer 340 or 342 from the metal core 310 and/or an adjacent metal circuit layer 340 or 342, and may have a thickness below approximately 60 μm to reduce a length of a current loop flowing across the dielectric coating 312 (e.g., between the metal core 310 and a metal circuit layer 340 or 342, between two metal circuit layers 340 above the metal core 310, between two metal circuit layers 342 below the metal core 310, and/or between a first metal circuit layer 340 above the metal core 310 and a second metal circuit layer 342 below the metal core). In this way, by reducing the length of the current loop that flows across the dielectric coating 312, the relatively small thickness of the dielectric coating 312 is associated with a low parasitic inductance. Furthermore, because the dielectric coating 312 has a low thermal resistance (e.g., based on the thickness of the dielectric coating 312 and/or a thermal conductivity of the dielectric material used for the dielectric coating), the dielectric coating 312 can effectively block or insulate an electric current without significantly impacting heat flow vertically into and/or out of the metal core 310.

As indicated above, FIGS. 3A-3B are provided as examples. Other examples may differ from what is described with regard to FIGS. 3A-3B.

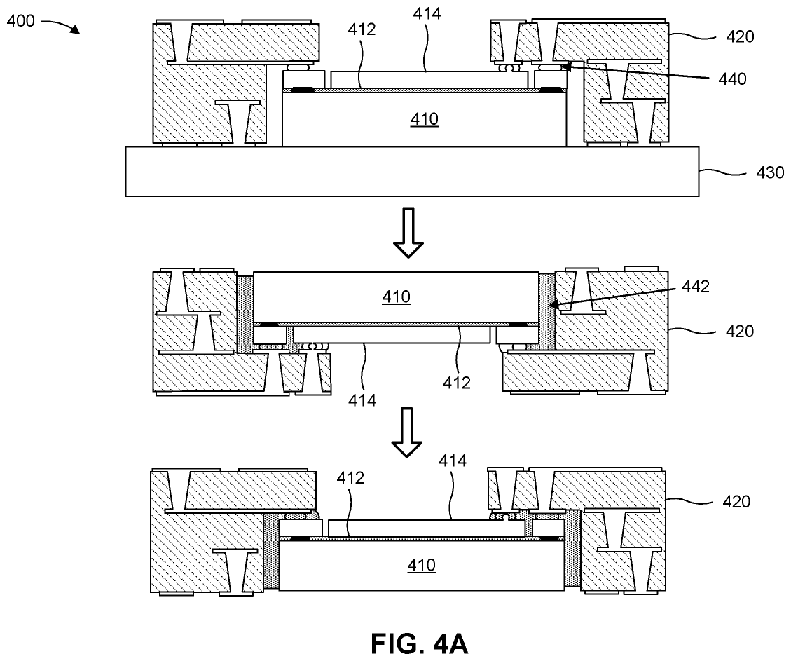

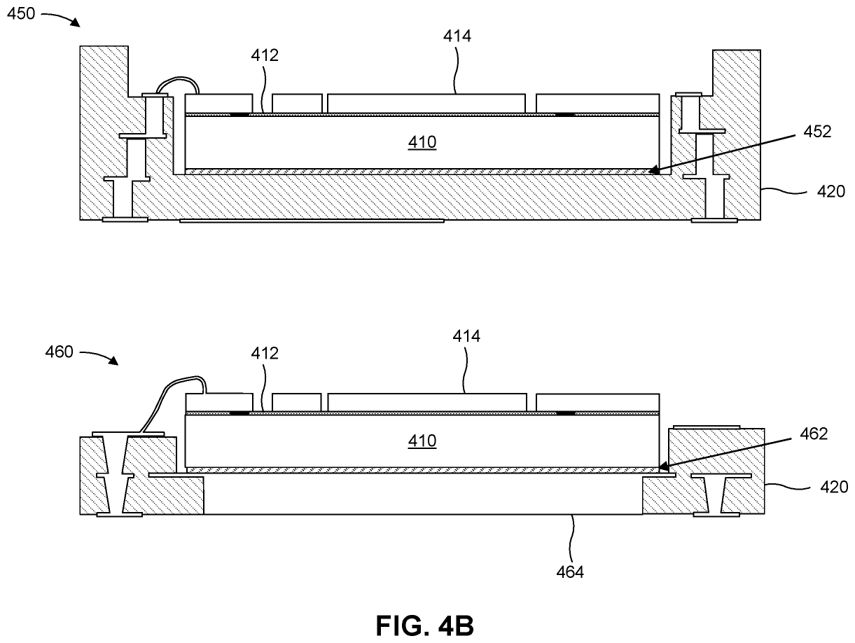

FIGS. 4A-4B are diagrams illustrating example implementations 400, 450, 460 of a package or hybrid substrate that includes a submount with a low thermal resistance and a low parasitic inductance.

For example, as shown in FIGS. 4A-4B, the submount may include a metal base block 410, which may be made from Cu, CuW, Al, or another suitable metal, a thin dielectric coating layer 412 on a top side of the metal base block 410, and a metal circuit layer 414 formed above the dielectric coating layer 412 (e.g., a single-metal-layer (1ML) on top). In some implementations, the dielectric coating layer 412 has a thickness in a range between approximately 0.2 μm and approximately 60 μm. For example, dielectric coating layer 412 may include AlPO₄ with a thickness between approximately 0.2-5 μm and/or AlON or MN with a thickness between approximately 10-20 μm. Accordingly, because the dielectric coating layer 412 is very thin (e.g., less than approximately 60 μm, and potentially as low as 0.2 μm), the dielectric coating layer 412 has a very low parasitic inductance, which is mainly impacted by the thickness of the dielectric coating layer 412. Furthermore, in some implementations, the dielectric coating layer 412 has a low thermal resistance to enable heat dissipation and/or spreading in the metal base block 410, which may be made from a thermally conductive metal (e.g., a metal that has a high thermal conductivity, such as Cu, CuW, or Al). For example, as described above, the thermal resistance of the dielectric coating layer 412 may be impacted by the thickness of the dielectric coating layer 412 and/or the thermal conductivity of the dielectric material used for the dielectric coating layer 412. Accordingly, the dielectric coating layer 412 has parasitic inductance and thermal resistance properties that ensure good electrical performance and heat dissipation and/or heat spreading in a circuit where electrical current and heat flows vertically through the package (e.g., through the submount).

For example, implementation 400 includes a package (e.g., a multi-layer hybrid substrate) in which the metal base block 410 may be used as a grounding layer and a heat dissipation layer. For example, in some implementations, the dielectric coating layer 412 may be grown on the metal base block 410 to a desired thickness, and one or more vias may then be formed in the dielectric coating layer 412 (e.g., by laser drilling followed by metal filling). In some implementations, the one or more vias may be used to connect one or more ground traces to the metal base block 410 such that the metal base block 410 may serve as a grounding layer. In some implementations, metal plating and patterning may then be performed to form the metal circuit layer 414 on the dielectric coating layer 412. As shown in FIG. 4A, the submount may be packaged into a substrate 420, which may be an organic substrate (e.g., an FR4 substrate) and/or an inorganic substrate (e.g., an HTCC substrate). For example, as shown in FIG. 4A, the submount may be placed on a bonding fixture 430, and the substrate 420 may include a cavity to receive the submount and an open window above the cavity (e.g., for emission of a laser). In some implementations, as shown by reference number 440, the submount may be electrically bonded to the substrate 420 by solder paste reflow, Cu-core or plastic-core solder ball reflow, thermal compression bonding of a gold (Au) stud, anisotropic conductive paste bonding, and/or anisotropic conductive film bonding, among other examples. In some implementations, as shown by reference number 442, the structure may then be flipped over and a gap between the submount and the substrate 420 may be filled with an electrically insulative epoxy to increase mechanical strength. In some implementations, the epoxy may be insulative, with a proper Young's modulus to adjust to a coefficient of thermal expansion (CTE) mismatch between the submount and the substrate 420.

In some implementations, as shown in the bottom diagram of FIG. 4A, the final finished package may include one or more circuit layers electrically connected to the metal circuit layer 414, and the metal base block 410 may serve as a ground and heat dissipation layer. For example, the thin dielectric coating layer 412 may electrically isolate the metal base block 410 used as the ground layer and electrically insulate an electrical current that flows vertically into the cavity region that holds the submount, and the dielectric coating layer 412 has a low parasitic inductance (attributable to the dielectric coating layer 412 having a small thickness) to improve electrical performance for the electrical current. In addition, as described herein, the thickness and/or thermal conductivity of the dielectric coating layer 412 may result in a low thermal resistance, which enables heat to be transferred to the metal base block 410 where the heat can be dissipated or otherwise spread.

FIG. 4B illustrates other example implementations 450, 460 of packages or hybrid substrates that include a submount with a metal base block 410, a single metal circuit layer 414 on top, and a thin dielectric coating layer 412 with a low parasitic inductance and a low thermal resistance to separate the metal circuit layer 414 from the metal base block 410 on the bottom of the submount. In example 450, the submount can be attached into a cavity of a ceramic or inorganic substrate 420 (e.g., an HTCC substrate) by an adhesive 452, such as solder, sintered silver (Ag) epoxy, semi-sintered Ag epoxy, or Ag epoxy, with a ground layer connected by a wire bond. Additionally, or alternatively, in example 460, an adhesive 462 may be used to attach the submount onto a conductive component 464 of an organic substrate 420 (e.g., an FR4 substrate), with a wire bond connection to the ground layer. For example, in some implementations, the conductive component 464 to which the submount is attached may include a Cu slug, an insert, or a coin of the organic substrate 420.

As indicated above, FIGS. 4A-4B are provided as examples. Other examples may differ from what is described with regard to FIGS. 4A-4B.

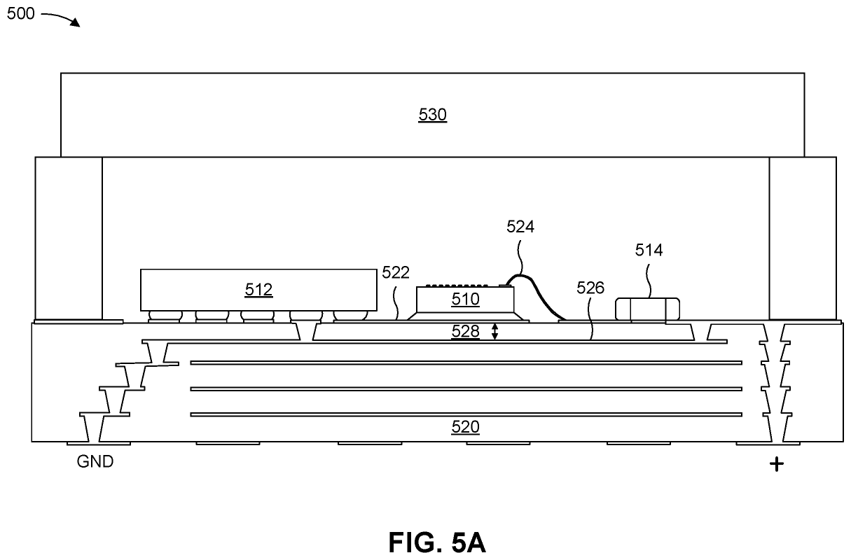

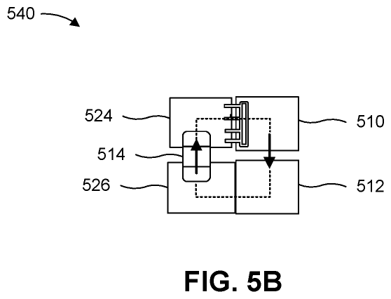

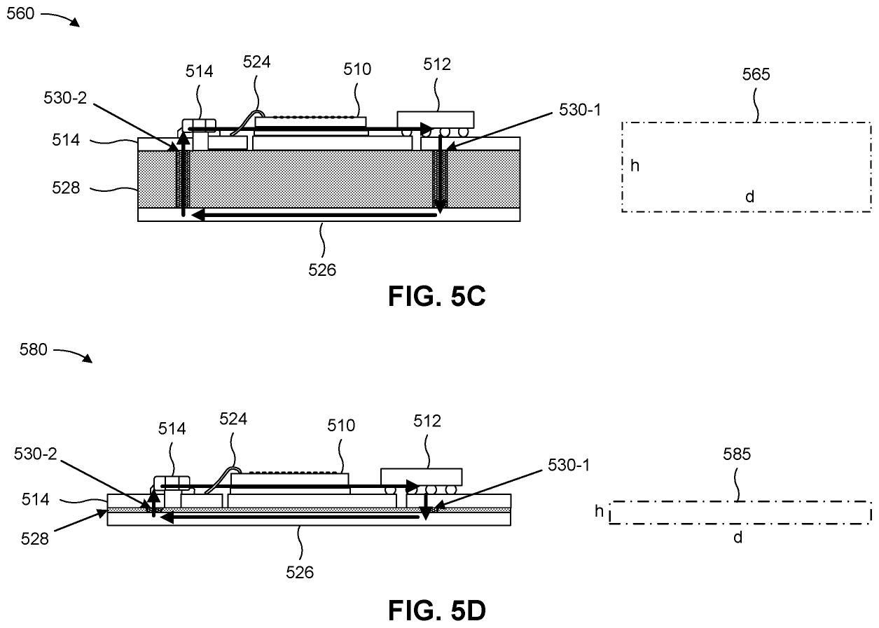

FIG. 5A is a diagram illustrating an example of a ToF projector module 500 in which a current loop may be formed to drive an optical load, and FIGS. 5B-5D are diagrams illustrating examples 540, 560, 580 of the current loop that may be used to drive the optical load in the ToF projector module 500. For example, as shown in FIG. 5A, the ToF projector module 500 may include a substrate 520 (e.g., an FR4 or HTCC substrate) with a top metal layer that includes a cathode 522 electrically connected to a bottom side of a VCSEL 510 and electrically connected to a driver 512, and the top metal layer may further include an anode 524 (shown as being electrically connected to one or more capacitors 514 and electrically connected to a top side of the VCSEL 510 using a wire bond). Furthermore, as shown, the substrate 520 includes a ground layer 526 as a second metal layer below the top metal layer, and a dielectric layer 528 that separates the top metal layer from the ground layer 526. Accordingly, when an electrical current flows through a set of circuit components arranged on the top metal layer (e.g., the VCSEL 510, the driver 512, and the capacitor(s) 514), the electrical current may cause the VCSEL 510 to emit a laser beam in a vertical direction through an optical element 530 (e.g., a diffractive optical element (DOE), a diffuser, a window, and/or a lens, among other examples), such that the ToF projector module 500 may be used as a VCSEL-based projector in a three-dimensional (3D) sensing camera application. However, as described in further detail above, the dielectric layer 528 that is provided between the top metal layer and the ground layer 526 poses various design challenges because the dielectric layer 528 needs to be very thin in order to avoid parasitic inductance and needs to also have a low thermal resistance to enable heat dissipation.

For example, FIGS. 5B-5D illustrate examples 540, 560, 580 of electrical layouts that may be used to generate a high-speed current loop sufficient to drive a VCSEL array or another suitable optical load (e.g., in a ToF camera application). For example, one design challenge that arises in ToF applications is the need to reduce the parasitic inductance of the current loop that is needed to drive the VCSEL array (or other optical load) with a high speed and a high current. As shown in FIGS. 5B-5D, the high speed current loop may generally include a VCSEL 510, a driver 512, and one or more capacitators 514. In general, the electrical layout used to generate the high speed current loop may be implemented in one horizontal layer, or vertically in multiple metal layers. For example, in FIG. 5B, the current loop is provided in one horizontal layer, shown in a top view. In this case, a self-inductance of the current loop is proportional to a total length (or perimeter) of the current loop. Alternatively, FIG. 5C and FIG. 5D illustrate examples 560, 580 in which the current loop is provided vertically in two metal layers, shown in a side view. For example, as shown in FIG. 5C and FIG. 5D, the current loop may pass horizontally through one or more capacitors 514, a VCSEL 510, and a driver 512 that are arranged along a top metal layer 514 (e.g., a Cu, CuW, or Al metal layer), vertically through a first metal-filled via 530-1, horizontally through a second metal layer 526 connected to ground, and through a second metal-filled via 530-2. In such cases, the dielectric layer 528 may need to be as thin as possible in order to provide a low parasitic inductance, and the dielectric layer 528 also needs to have a low thermal resistance in order to enable heat dissipation and/or heat spreading in the second metal layer 526. However, satisfying the electrical and thermal requirements for a high-speed current loop is difficult when existing dielectric materials are used to form the dielectric layer 528.

For example, in FIG. 5C, example 560 depicts an arrangement in which the dielectric layer 528 is made from a ceramic material (e.g., Al₂O₃ or aluminum nitride (AlN) HTCC), in which case the dielectric layer 528 may have a large thickness (e.g., a minimum thickness of 100 μm for AlN, or a minimum thickness of 70 μm for Al₂O₃, and a thickness greater than 150 μm for two layers due to processing and material restrictions). As a result, even though the ceramic dielectric material may have a somewhat higher thermal conductivity than a polymer dielectric such as FR4 (e.g., 130 W/mK for AlN or 15 W/mK for Al₂O₃ at a typical VCSEL operating temperature), the ceramic dielectric material may still cause thermal problems for VCSELs, laser chips, and/or other devices that generally are more power efficient at lower temperatures. For some applications (e.g., an automotive light detection and radar (LIDAR sensor), a laser peak power can be as high as hundreds of watts, whereby a substrate design that has a low thermal resistance is desirable. Furthermore, the large thickness of the dielectric layer 528 increases parasitic inductance to a higher level that has an impact on high-speed signal quality (e.g., by degrading high-speed modulation performance). Furthermore, to the extent that other dielectric materials such as FR4 associated with a minimum thickness of 25 μm may be used, such dielectric materials have a prohibitively high thermal resistance that is unsuitable for use in the ToF projector module 500 that needs to spread and/or dissipate the large amount of heat that is generated by the high speed current loop.

For example, as shown by reference number 565, the rectangular shaped current loop may have a self-inductance approximately proportional to an area of the current loop, defined using the expression h*d, where d is a horizontal dimension of the circuit components forming the current loop (e.g., the capacitor(s) 514, the VCSEL 510, and the driver 512), and h is a vertical dimension of the layers forming the current loop (e.g., a combined thickness of the top metal layer 514 and the dielectric layer 528). In general, the horizontal dimension d is typically limited by the size of the circuit components. However, the vertical dimension h of the current loop may vary depending on the thickness of the dielectric layer 528.

Accordingly, in FIG. 5D, example 580 illustrates a design in which the dielectric layer 528 separating the top metal layer 514 from the second metal layer 526 is a thin dielectric coating, such as AlON, AlN, or AlPO₄ with a thickness in a range between 0.2 μm (or 200 nanometers) and 60 μm, which significantly reduces the self-inductance of the current loop and provides the heat dissipation needed for high speed and high current operation. For example, in some implementations, the dielectric layer 528 in FIG. 5D may have the same properties as the dielectric coatings 312 described above with reference to FIGS. 3A-3B and/or the thin dielectric coating layer 412 described above with reference to FIGS. 4A-4B. Accordingly, as shown by reference number 585, reducing the thickness of the dielectric layer 528 can significantly reduce the vertical dimension h of the current loop and thereby significantly reduce the self-inductance. For example, using a thin dielectric coating as the dielectric layer 528 (e.g., as shown in FIG. 5D) may reduce the vertical dimension h to be less than 50 μm, which may result in a 2× reduction in the self-inductance. For example, as described herein, the thickness of the dielectric layer 528 may be approximately 5 μm to 20 μm for AlON or approximately 0.2 μm to 5 μm for AlPO₄ dielectric materials, and the thickness of the top metal layer 514 may be 18 μm, which may result in the vertical dimension h having a maximum value of 38 μm in cases where AlON or AlPO₄ is used to form the dielectric layer 528. Accordingly, whereas the self-inductance in a current loop formed horizontally in one metal layer is generally proportional to the total length of the current path (e.g., 2h+2d, as in FIG. 5B), the total self-inductance of the current loop formed in two metal layers is proportional to the area enclosed by the current loop (e.g., h*d). Therefore, reducing the vertical dimension h by a given amount (e.g., 1 μm) will generally have a larger impact with respect to reducing the total inductance relative to reducing the horizontal dimension d by the same amount in a design where the total inductance of the current loop is proportional to the total length of the current path. Also, reducing either dimension by a given amount will have a larger impact on the total inductance when the inductance is proportional to the area (e.g., h*d for vertical current loops) rather than the perimeter (e.g., 2h+2d for horizontal current loops).

Some implementations described in further detail herein therefore relate to one or more ToF projector modules that may have a design based on the substrate designs shown in FIGS. 3A-3B and/or the package or hybrid substrate designs shown in FIGS. 4A-4B. In this way, in a ToF projector module where a high speed current loop is formed in two metal layers, using a thin dielectric coating between the top metal layer 514 and the second metal layer 526 (e.g., as shown in FIG. 5D) may reduce the self-inductance by more than 2× compared to a design that utilizes a conventional HTCC or thin film substrate (e.g., as shown in FIG. 5C), in addition to providing significantly lower thermal resistance than other thin dielectric materials associated with a prohibitively low thermal conductivity or a prohibitively high thermal resistance when used in high speed, high current applications such as a ToF camera projector module. For example, although FR4 may be formed with a minimum thickness of 25 μm using advanced substrate technology, which provides a lower parasitic inductance than an HTCC dielectric with a minimum thickness of 100 μm, FR4 is associated with a very low thermal conductivity (e.g., between 0.3 to 0.7 W/mK) and a very high thermal resistance (e.g., 46.61 C/W at the minimum thickness of 25 μm), whereby FR4 is unsuitable to dissipate and/or spread the heat that is generated by a high-power VCSEL-based ToF projector module.

As indicated above, FIGS. 5A-5D are provided as examples. Other examples may differ from what is described with regard to FIGS. 5A-5B.

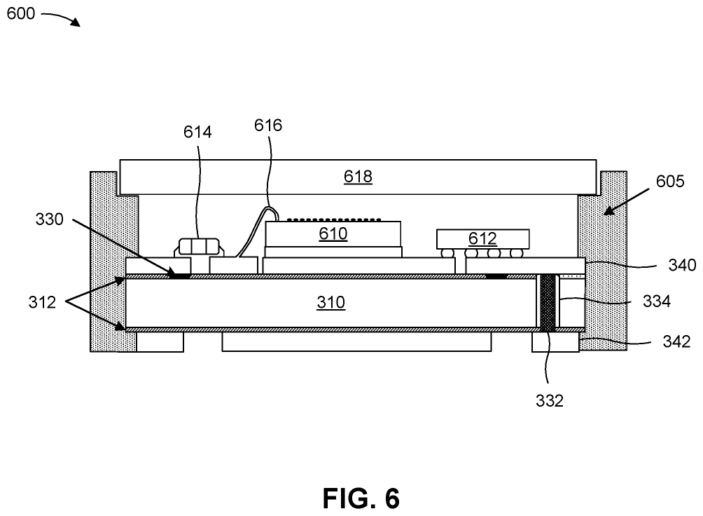

FIG. 6 is a diagram illustrating an example implementation 600 of a ToF projector module in which a current loop used to drive an optical load is formed vertically across two metal layers in a substrate with a low thermal resistance and a low parasitic inductance. For example, as shown in FIG. 6, the substrate includes a metal core 310, a top metal layer 340, a bottom metal layer 342, a first dielectric coating layer 312 that separates the metal core 310 from the top metal layer 340, and a second dielectric coating layer 312 that separates the metal core 310 from the bottom metal layer 340. In some implementations, the dielectric coating layers 312 may include AlON, with a thickness in a range between approximately 5 μm and 20 μm and a thermal resistance under 15 C/W (e.g., approximately 12.58 C/W for a 2×20 μm AlON dielectric coating layer 312 formed on a 100 μm thick Cu metal core 310, or approximately 12.78 C/W for a 2×20 μm AlON dielectric coating layer 312 formed on a 100 μm thick CuW metal core 310). In another example, the dielectric coating layers 312 may include AlPO₄, with a thickness in a range between approximately 0.2 μm and 5 μm and a thermal resistance under 15 C/W (e.g., approximately 12.33 C/W for a 2×0.5 μm AlPO₄ dielectric coating layer 312 formed on a 100 μm thick Cu metal core 310). Additionally, or alternatively, the dielectric coating layers 312 may be made from another suitable dielectric material, such as AlN, with a thickness under 60 μm to provide a low parasitic inductance, and thickness and/or a thermal conductivity that results in a low thermal resistance to allow heat to be spread and/or dissipated in the metal core 310. Furthermore, as shown in FIG. 6 and described in further detail above with reference to FIGS. 3A-3B, the substrate may include one or more metal-filled vias 330 through a dielectric coating layer 312 to provide an electrical connection to the metal core 310, and one or more vias 332 through the metal core 310, which are filled with a dielectric epoxy 334 and a metal, to provide an electrical connection between a metal layer 340 above the metal core 310 and a metal layer 342 below the metal core 310.

As shown in FIG. 6, the top metal layer 340 of the substrate may be a patterned circuit layer that includes an anode and a cathode, and one or more circuit components may be arranged on the top metal layer 340 to form a high-speed current loop. For example, the one or more circuit components may include a VCSEL 610 having a bottom side that is connected to the cathode and a top side that is connected to the anode using a wire bond 616, a driver 612 connected to the cathode, and one or more capacitors 614 connected to the anode. Accordingly, a current loop may pass horizontally through the capacitor(s) 614, the VCSEL 610, and the driver 612, vertically across the dielectric coating layer 312 and into the metal core 310 through a first metal-filled via 330 located under the driver 612, horizontally along the metal core 310, and vertically across the dielectric coating layer 312 and into the top metal layer 340 through a second metal-filled via 330 located under the capacitor(s) 614. As further shown, the substrate may be attached to a housing 605 (e.g., a pre-molded plastic housing with an open cavity formed by a film-assisted molding process) using any suitable technique to increase a mechanical strength of the substrate. Accordingly, an optical element 618 (e.g., a DOE, a diffuser, a window, or a lens) may be attached to the housing 605 such that the VCSEL 610 emits a laser in a vertical direction through the optical element 618 when the current loop is formed between the metal core 310 and the top metal layer 340. In this way, the substrate designs shown in FIGS. 3A-3B may be used to form a ToF projector module in which a current loop that is used to drive the optical load (e.g., the VCSEL 610) is associated with a low parasitic inductance due to the dielectric coating layers 312 having a thickness between approximately 0.2 μm to 60 μm and a thermal resistance under 15 C/W due to the thickness of the dielectric coating layers 312 and/or the thermal conductivity of the materials used to form the dielectric coating layers 312.

As indicated above, FIG. 6 is provided as an example. Other examples may differ from what is described with regard to FIG. 6.

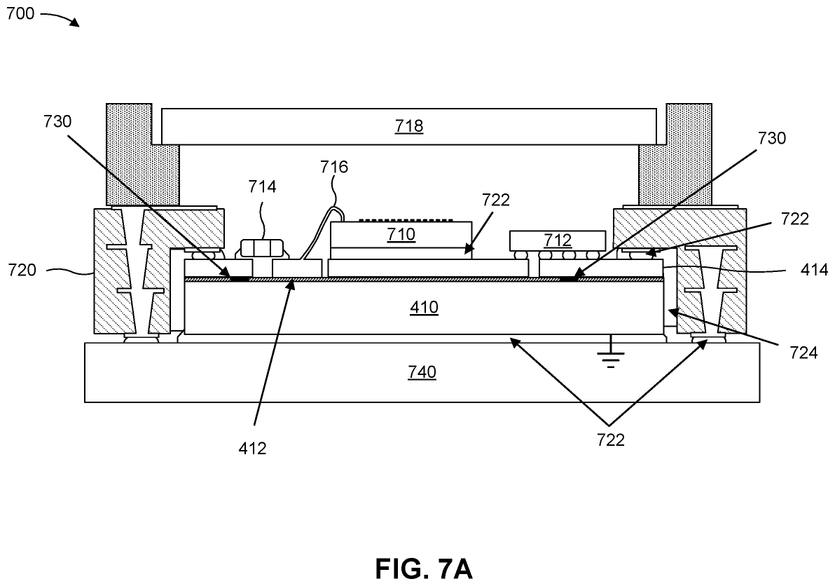

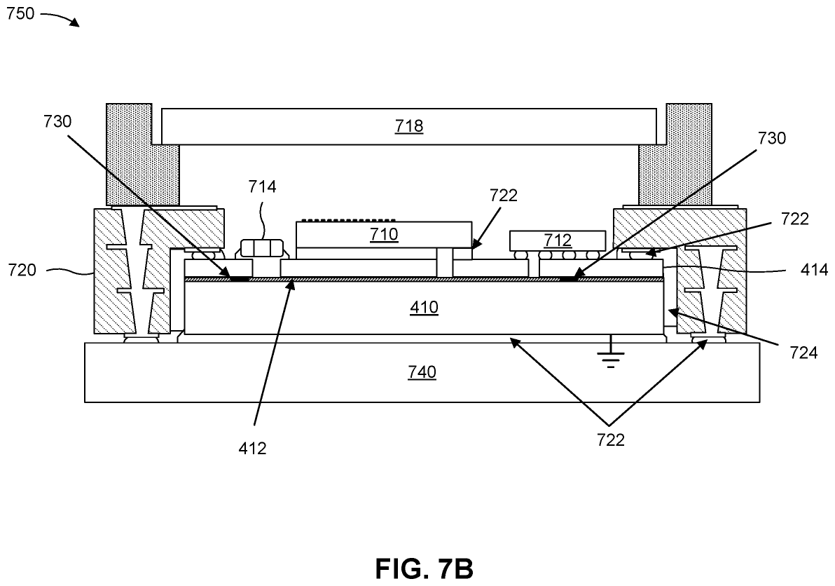

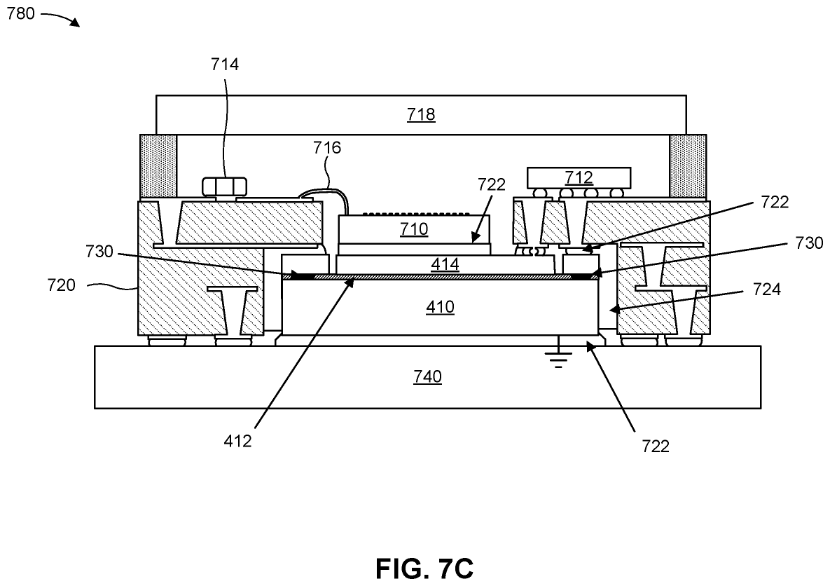

FIGS. 7A-7C are diagrams illustrating example implementations 700, 750, 780 of a ToF projector module in which a current loop used to drive an optical load is formed vertically across two metal layers in a submount with a low thermal resistance and a low parasitic inductance.

For example, as shown in FIGS. 7A-7C, the submount may include a metal base block 410, which may be made from Cu, CuW, Al, or another suitable metal, a thin dielectric coating layer 412 on a top side of the metal base block 410, and a metal circuit layer 414 formed above the dielectric coating layer 412 (e.g., a single-metal-layer (1ML) on top). In some implementations, the dielectric coating layer 412 has a thickness in a range between approximately 0.2 μm and approximately 60 μm. For example, dielectric coating layer 412 may include AlPO₄ with a thickness between approximately 0.2 and 5 μm and/or AlON or MN with a thickness between approximately 10 and 20 μm. Accordingly, because the dielectric coating layer 412 is very thin (e.g., less than approximately 60 μm, and potentially as low as 0.2 μm), the dielectric coating layer 412 has a very low parasitic inductance, which is mainly impacted by the thickness of the dielectric coating layer 412. For example, as shown in FIGS. 7A-7B, the top metal circuit layer 414 may be patterned to include an anode that is connected to one or more capacitors 714 and to a VCSEL 710 (e.g., using a wire bond 716 as shown in FIG. 7A, or directly when the VCSEL 710 is a backside-emitting VCSEL chip, as in FIG. 7B). For example, in FIG. 7A, the wire bond 716 electrically connects a top side of the VCSEL chip 710 to a pad (e.g., the anode) that is also connected to the one or more capacitors 714, and the top metal circuit layer 414 includes a larger pad (e.g., the cathode) that is electrically connected to the bottom side of the VCSEL 710 and the driver 712. In contrast, in FIG. 7B where the VCSEL 710 is a backside-emitting VCSEL chip, the cathode is the smaller pad electrically connecting to the driver 712 and the bottom side of the VCSEL 710, and the larger pad is the anode used to carry electrical current and dissipate heat generated by the electrical current. Referring to FIG. 7C, example implementation 780 differs from example implementations 700 and 750 in that the capacitor(s) 714 and the driver 712 are not arranged on the metal circuit layer 414, but are instead provided on pads located on a top side of the substrate 720 (e.g., the with top side of the VCSEL 710 connected to the anode via a wire bond 716). In this case, the horizontal dimension of the current loop may be decreased, allowing the ToF projector to occupy a smaller area, although the vertical dimension is increased relative to an arrangement in which the capacitor(s) 714, the VCSEL 710, and the driver 712 are all arranged on the metal circuit layer 414.

In some implementations, in FIGS. 7A-7C, signal routing for a current loop used to drive the optical load 710 may be similar to the current loop shown in FIG. 5D, where the current loop may pass horizontally through the capacitor(s) 714, the VCSEL 710, and the driver 712, vertically across the dielectric coating layer 412 and into the metal base block 410 through a first metal-filled via 730 located under the driver 712, horizontally along the metal base block 410, and vertically across the dielectric coating layer 412 and into the metal circuit layer 414 through a second metal-filled via 730 located under the capacitor(s) 714. Accordingly, as described above, a self-inductance of the current loop may be proportional to an area enclosed by the current loop, which may include a vertical dimension that is based on a combined thickness of the metal circuit layer 414 and the dielectric coating layer 412. Because the dielectric coating layer 412 has a thickness in a range between approximately 0.2 μm and approximately 60 μm, which may be as low as 5 μm when the dielectric coating layer 412 is made from AlON or MN or 0.2 μm when the dielectric coating layer 412 is made from AlPO₄, the self-inductance of the current loop is significantly lower than designs where the dielectric coating layer 412 is made using a conventional HTCC or thin film substrate with a minimum thickness of 100 μm. Furthermore, in some implementations, the dielectric coating layer 412 has a low thermal resistance to enable heat dissipation and/or spreading in the metal base block 410, which may be made from a thermally conductive metal (e.g., a metal that has a high thermal conductivity, such as Cu, CuW, or Al). For example, as described above, the thermal resistance of the dielectric coating layer 412 may be impacted by the thickness of the dielectric coating layer 412 and/or the thermal conductivity of the dielectric material used for the dielectric coating layer 412. Accordingly, the dielectric coating layer 412 has parasitic inductance and thermal resistance properties that ensure good electrical performance and heat dissipation and/or heat spreading in a circuit where electrical current and heat flows vertically through the package (e.g., through the submount).

For example, as shown in FIG. 7A, example implementation 700 includes a package (e.g., a multi-layer hybrid substrate) in which the metal base block 410 may be used as a grounding layer and a heat dissipation layer. For example, in some implementations, the dielectric coating layer 412 may be grown on the metal base block 410 to a desired thickness, and one or more vias 730 may then be formed in the dielectric coating layer 412 (e.g., by laser drilling followed by metal filling). In some implementations, the one or more vias 730 may be used to connect one or more ground traces to the metal base block 410 such that the metal base block 410 may serve as a ground layer. In some implementations, metal plating and patterning may then be performed to form the metal circuit layer 414 on the dielectric coating layer 412. As shown in FIGS. 7A-7C, the submount may be packaged into a substrate 720, which may be an organic substrate (e.g., an FR4 substrate) and/or an inorganic substrate (e.g., an HTCC substrate). For example, as shown in FIGS. 7A-7C, the substrate 720 may include a cavity to receive the submount and an open window above the cavity (e.g., for emission of a laser). In some implementations, as shown by reference number 722, the submount may be electrically bonded to the substrate 720 by solder paste reflow, Cu-core or plastic-core solder ball reflow, thermal compression bonding of an Au stud, anisotropic conductive paste bonding, and/or anisotropic conductive film bonding, among other examples, the VCSEL 710 may be attached to the cathode by solder, Ag epoxy, or another electrically conductive attachment, and the substrate 720 and submount may be electrically bonded to a printed circuit board (PCB) 740 by solder, Ag epoxy, or another electrically conductive attachment. As further shown by reference number 724, a gap between the submount and the substrate 720 may be filled with an electrically insulative epoxy to increase mechanical strength, where the epoxy may be insulative, with a proper Young's modulus to adjust to a CTE mismatch between the submount and the substrate 720. In some implementations, an optical element 718 may be placed in the open window above the VCSEL 710, whereby the current loop may cause the VCSEL 710 to emit a laser in a vertical direction through the optical element 718 (e.g., a DOE, a diffuser, a window, or a lens).

As indicated above, FIGS. 7A-7C are provided as examples. Other examples may differ from what is described with regard to FIGS. 7A-7C.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A circuit, comprising:
a top metal layer that includes an anode and a cathode;
one or more capacitors connected to the anode;
a vertical-cavity surface-emitting laser (VCSEL) connected to the anode and the cathode;
a driver connected to the cathode;
a bottom metal layer arranged below the top metal layer,
wherein the bottom metal layer is connected to ground; and
a dielectric layer separating the top metal layer and the bottom metal layer,
wherein the dielectric layer has a thickness under sixty micrometers and a thermal resistance under fifteen degrees Celsius per watt,
wherein a current loop flowing vertically across the dielectric layer has a low self-inductance based on the thickness of the dielectric layer, and
wherein the bottom metal layer is arranged to dissipate heat generated by the current loop flowing vertically across the dielectric layer.

2. The circuit of claim 1, wherein the current loop flows horizontally through the one or more capacitors, the VCSEL, and the driver, vertically across the dielectric layer, horizontally through the bottom metal layer, and vertically across the dielectric layer.

3. The circuit of claim 1, wherein the self-inductance of the current loop is proportional to an area enclosed by the current loop.

4. The circuit of claim 3, wherein the area enclosed by the current loop includes a vertical dimension based on a combined thickness of the dielectric layer and the top metal layer.

5. The circuit of claim 1, further comprising:
a first metal-filled via, through the dielectric layer, to provide an electrical connection between the bottom metal layer and the driver, and
a second metal-filled via, through the dielectric layer, to provide an electrical connection between the bottom metal layer and the one or more capacitors.

6. The circuit of claim 1, wherein the dielectric layer includes aluminum oxynitride (AlON), and the thickness of the dielectric layer is twenty micrometers or less.

7. The circuit of claim 1, wherein the dielectric layer includes aluminum phosphate (AlPO₄), and the thickness of the dielectric layer is five micrometers or less.

8. A projector module, comprising:
a housing;
a substrate attached to the housing, wherein the substrate includes:
a metal core having a top side and a bottom side;
a first metal circuit layer formed above the top side of the metal core;
a second metal circuit layer formed below the bottom side of the metal core;
a first dielectric coating separating the metal core from the first metal circuit layer; and
a second dielectric coating separating the metal core from the second metal circuit layer,
wherein the first dielectric coating and the second dielectric coating have respective thicknesses that are each less than sixty micrometers and respective thermal resistances that are each less than fifteen degrees Celsius per watt;
one or more circuit components on the first metal circuit layer, wherein the one or more circuit components include:
one or more capacitors;
a driver; and
a vertical-cavity surface-emitting laser (VCSEL) connected to the one or more capacitors and the driver,
wherein a current loop flowing horizontally through the one or more circuit components and vertically across at least the first dielectric coating causes the VCSEL to emit a laser beam in a vertical direction, and
wherein the current loop has a low self-inductance based on the thickness of at least the first dielectric coating.

9. The projector module of claim 8, wherein the first dielectric coating and the second dielectric coating include one or more of aluminum oxynitride (AlON), aluminum nitride (AlN), or aluminum phosphate (AlPO₄).

10. The projector module of claim 8, further comprising:
an optical element attached to the housing and arranged above the VCSEL,
wherein the optical element includes one or more of a diffractive optical element, a diffuser, a window, or a lens.

11. The projector module of claim 8, wherein the self-inductance of the current loop is proportional to an area enclosed by the current loop.

12. The projector module of claim 11, wherein the area enclosed by the current loop includes a vertical dimension based on a combined thickness of the first dielectric coating and the first metal circuit layer.

13. The projector module of claim 8, wherein the substrate further includes:
a first metal-filled via, through the first dielectric coating, to provide an electrical connection between the metal core and the driver, and
a second metal-filled via, through the first dielectric coating, to provide an electrical connection between the metal core and the one or more capacitors.

14. The projector module of claim 13, wherein the current loop flows horizontally through the one or more circuit components on the first metal circuit layer, vertically through the first metal-filled via, horizontally through the metal core, and vertically through the second metal-filled via.

15. A projector module, comprising:
a substrate that includes a cavity;
a submount, bonded to the cavity in the substrate, wherein the submount includes:
a metal base block;
a dielectric coating on a top side of the metal base block,
wherein the dielectric coating has a thickness that is twenty micrometers or less; and
a metal circuit layer formed above the dielectric coating; and
one or more circuit components on the metal circuit layer, wherein the one or more circuit components include:
one or more capacitors;
a driver; and
a vertical-cavity surface-emitting laser (VCSEL) connected to the one or more capacitors and the driver,
wherein a current loop flowing horizontally through the one or more circuit components and vertically across at least the dielectric coating causes the VCSEL to emit a laser beam in a vertical direction, and
wherein the current loop has a low self-inductance and a low thermal resistance based on the thickness of the dielectric coating.

16. The projector module of claim 15, wherein the dielectric coating includes aluminum oxynitride (AlON) or aluminum phosphate (AlPO₄).

17. The projector module of claim 15, wherein the metal base block is connected to ground and arranged to dissipate heat generated by the current loop that causes the VCSEL to emit the laser beam in the vertical direction.

18. The projector module of claim 15, further comprising:
an optical element arranged in a window above the VCSEL,
wherein the optical element includes one or more of a diffractive optical element, a diffuser, a window, or a lens.

19. The projector module of claim 15, wherein the self-inductance of the current loop is proportional to an area enclosed by the current loop.

20. The projector module of claim 19, wherein the area enclosed by the current loop includes a vertical dimension based on a combined thickness of the dielectric coating and the metal circuit layer.
